(19) United States
(12) Patent Application Publication
(10) Pub. No.: US 2021/0367190 A1
(43) Pub. Date: Nov. 25, 2021

(54) ENCAPSULATION STRUCTURE OF OLED DEVICE AND DISPLAY PANEL

(71) Applicant: WUHAN CHINA STAR OPTOELECTRONICS SEMICONDUCTOR DISPLAY TECHNOLOGY CO., LTD., Wuhan (CN)

(72) Inventor: Yue Zhang, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/316,866

(22) PCT Filed: Aug. 31, 2018
(86) PCT No.: PCT/CN2018/103583

§ 371 Date: Jan. 10, 2019

(30) Foreign Application Priority Data
Jul. 11, 2018 (CN) 201810754858.5

(51) Int. Cl. H01L 51/52

(52) U.S. Cl. CPC H01L 51/5246; H01L 51/5259

(57) ABSTRACT

The invention provides an encapsulation structure of an organic light-emitting diode device, including: a substrate formed with the OLED device and an encapsulation cover plate disposed on the substrate, wherein the encapsulation cover plate is provided with a first recess and a second recess, the second recess is surrounds the first recess, the OLED device is disposed in the first recess, and an adhesive material is disposed in the second recess to adhere and fix the encapsulation cover plate to the substrate formed with the OLED device.

### FIELD OF INVENTION

The present invention relates to the field of display technologies, and in particular to an encapsulation structure of an organic light emitting diode (OLED) device and a display panel.

### BACKGROUND OF INVENTION

Current organic light emitting diodes (OLEDs) realize luminescence by vapor-depositing an organic thin film material and a metal cathode material on a glass substrate coated with an anode material, but because the organic thin film materials are mostly sensitive to oxygen and water vapor in the atmosphere and may fail due to a chemical reaction with oxygen and water vapor, the metal cathode material may be electrochemically corroded due to contact with water vapor. Therefore, the OLED light-emitting area must be effectively insulated from water and oxygen by encapsulation of the OLED device to prolong working life of the OLED device.

For this moment, the most common way of encapsulation mainly uses a sealant cured by ultraviolet (UV) light. However, because the cover glass and the substrate are planarly contacted, if the cover glass or the substrate is not flat or there are foreign bodies between the cover glass and the substrate, this results in that the UV-curable adhesive may not be completely pressed together during the pressing process, and causes connection discontinuity and bubbles, and even if the UV-curable adhesive is completely pressed together and cured by exposure to an ultraviolet light, the UV-cured adhesive may shrink to form a discontinuous connection, so that the internal organic material may be exposed to the risk of being reacting with water and oxygen, resulting in reduced reliability of the OLED device encapsulation, water and oxygen resistance capability of the OLED device, and service life of the OLED device.

Technology problem: because the cover glass and the substrate are planarly contacted, if the cover glass or the substrate is not flat or there are foreign bodies between the cover glass and the substrate, this results in that the UV-curable adhesive may not be completely pressed together during the pressing process, and causes connection discontinuity and bubbles, and even if the UV curable adhesive is completely pressed together and cured by exposure to an ultraviolet light, the UV-cured adhesive may shrink to form a discontinuous connection.

### SUMMARY OF INVENTION

The technical solution provided by the present invention is as follows:

The embodiment of the invention provides an encapsulation structure of an OLED device, which can improve the reliability of encapsulation of the OLED device, so that improves the water and oxygen resistance of the OLED device and prolongs the service life of the OLED device.

The present invention provides an encapsulation structure of an organic light-emitting diode (OLED) device, including:

a substrate formed with the OLED device and an encapsulation cover plate disposed on the substrate, wherein the encapsulation cover plate is provided with a first recess and a second recess, the second recess is surrounds the first recess, the OLED device is disposed in the first recess, and an adhesive material is disposed in the second recess to adhere and fix the encapsulation cover plate to the substrate formed with the OLED device; and

the encapsulation structure of the OLED device further including a getter disposed in the first recess, and the getter surrounding the OLED device;

wherein a material of the getter is selected from the group consisting of titanium, zirconium, tantalum or thorium.

A preferred embodiment according to the present invention, the second recess comprises an upper wall, a first sidewall and a second sidewall disposed opposite to each other; the upper wall connected to the substrate, and the first sidewall disposed on a side of the upper wall adjacent to the first recess;

wherein a distance between the first sidewall and the second sidewall ranges from 0.3 mm to 0.7 mm, and a distance between the first sidewall and the first recess ranges from 1 mm to 5 mm.

A preferred embodiment according to the present invention, a depth of the first recess is greater than a depth of the second recess.

A preferred embodiment according to the present invention, a chamfer is further formed between the first recess and the second recess, to avoid bubbles and discontinuous of connections from appearing when the encapsulation cover plate is attached to the substrate.

A preferred embodiment according to the present invention, the chamfer has an acute angle, and an angle of the chamfer ranges from 5 to 15 degrees.

A preferred embodiment according to the present invention, the getter is a ring structure to increase a contact area of the getter with water and oxygen.

A preferred embodiment according to the present invention, the getter comprises an outer sidewall and an inner sidewall, and the outer sidewall and the inner sidewall is disposed opposite to each other; and

wherein the inner sidewall is disposed on a side of the getter closed to the OLED device, and a distance between the inner sidewall and the outer sidewall ranges from 1 mm to 5 mm.

The present invention provides an encapsulation structure of an OLEO device, including:

a substrate formed with the OLED device and an encapsulation cover plate disposed on the substrate,

wherein the encapsulation cover plate is provided with a first recess and a second recess, the second recess is surrounds the first recess, the OLED device is disposed in the first recess, and an adhesive material is disposed in the second recess to adhere and fix the encapsulation cover plate to the substrate formed with the OLED device.

A preferred embodiment according to the present invention, the encapsulation structure of the OLED device further comprises a getter disposed in the first recess, and the getter surrounding the OLED device.

A preferred embodiment according to the present invention, the second recess comprises an upper wall, a first sidewall and a second sidewall disposed opposite to each other; the upper wall connected to the substrate; and the first sidewall disposed on a side of the upper wall adjacent to the first recess,

wherein a distance between the first sidewall and the second sidewall ranges from 0.3 mm to 0.7 mm, and a distance between the first sidewall and the first recess ranges from 1 mm to 5 mm.

A preferred embodiment according to the present invention, a depth of the first recess is greater than a depth of the second recess.

A preferred embodiment according to the present invention, a chamfer is further formed between the first recess and the second recess, to avoid bubbles and discontinuous of connections from appearing when the encapsulation cover plate is attached to the substrate.

A preferred embodiment according to the present invention, the chamfer has an acute angle, and an angle of the chamfer ranges from 5 to 15 degrees.

A preferred embodiment according to the present invention, the getter is a ring structure to increase a contact area of the getter with water and oxygen.

A preferred embodiment according to the present invention, the getter comprises an outer sidewall and an inner sidewall, and the outer sidewall and the inner sidewall is disposed opposite to each other; and

wherein the inner sidewall is disposed on a side of the getter closed to the OLED device, and a distance between the inner sidewall and the outer sidewall ranges from 1 mm to 5 mm.

A preferred embodiment according to the present invention, a material of the getter is selected from the group consisting of titanium, zirconium, tantalum or thorium.

The present invention further provides an OLED display panel including an encapsulation structure of an OLED device, the encapsulation structure of the OLEO device comprising:

a substrate formed with the OLED device and an encapsulation cover plate disposed on the substrate,

wherein the encapsulation cover plate is provided with a first recess and a second recess, the second recess is surrounds the first recess, the OLED device is disposed in the first recess, and an adhesive material is disposed in the second recess to adhere and fix the encapsulation cover plate to the substrate formed with the OLED device.

A preferred embodiment according to the present invention, a depth of the first recess is greater than a depth of the second recess.

A preferred embodiment according to the present invention, a chamfer is further formed between the first recess and the second recess, to avoid bubbles and discontinuous of connections from appearing when the encapsulation cover plate is attached to the substrate.

A preferred embodiment according to the present invention, the chamfer has an acute angle, and an angle of the chamfer ranges from 5 to 15 degrees.

Beneficial effects: the beneficial effects of the invention are: the reliability of the OLED device encapsulation is improved by providing with the first recess and the second recess hi the encapsulation cover plate, and disposing the adhesive material in the second recess, so that improves the capability of water and oxygen resistance of the OLED device, and prolongs the service life of the OLED device.

### DESCRIPTION OF DRAWINGS

To more clearly illustrates the technical solutions in the embodiments of the present invention, the drawings used in the description of the embodiments will be briefly described below. It is apparent that the drawings accompanying with the following description are only some embodiments of the present invention. Other drawings can also be obtained from those skilled in the art based on these drawings without paying any creative effort.

FIG. 1 is a schematic cross-sectional view and shows an encapsulation structure of an OLED device according to an embodiment of the present invention;

FIG. 2 is a schematic cross-sectional view and shows an encapsulation structure of an OLED device according to a preferred embodiment of the present invention;

FIG. 3 is a schematic plan view and shows an encapsulation structure of an OLEO device according to a preferred embodiment of the present invention;

FIG. 4 is a schematic structural representation of an encapsulation cover plate of an OLEO device according to a preferred embodiment of the present invention;

FIG. 5 is a schematic cross-sectional view of an encapsulation cover plate of an OLED device according to a preferred embodiment of the present Invention;

FIG. 6 is a schematic structural representation of a getter according to an embodiment of the present invention.

### DETAILED DESCRIPTION OF PREFERRED EMBODIMENTS

The embodiments of the present invention are described in detail below, and the examples of the implementation are illustrated in the drawings, and the same or similar reference numerals indicate the same or similar elements or elements having the same or similar functions. The embodiments described below with reference to the drawings are intended to be illustrative of the present invention and cannot be understood as limitations of the present invention.

In the description of the present invention, it is to be understood that the terms “center”, “longitudinal”, “transverse”, “length”, “width”, “thickness”, “upper”, “lower”, “front”, “back”, “left”, “right”, “vertical”, “horizontal”, “top”, “bottom”, “inner”, “outer”, “clockwise”, “counterclockwise”, etc., indicated orientation or positional relationship are based on the orientation or positional relationship shown in the drawings, and are merely for the convenience of describing the present invention and simplifying the description, instead of Indicating or implying that the device or component referred to must have a particular orientation, constructed and operated in a particular orientation, Therefore, it cannot be constructed as a limitation of the present invention. Moreover, the terms “first” and “second” are only used for descriptive purposes and are not to be construed as indicating or implying a relative importance or implicitly indicating the number of technical features indicated. Thus, features defined “first” or “second” may include one or more features either explicitly or implicitly. In the description of the present invention, the term “a plurality of” may be two or more than two, unless otherwise specifically defined.

In the description of the present invention, it should be noted that the terms “mount”, “connect to”, and “connection” should be understood broadly, for example, it can be a fixed connection, a removeable connection, or connected in one piece; it can be a mechanical connection, it can also be electrically connected or can be communicated with each other; it can be directly connected, it can also be indirectly connected through an intermediary medium. It can be the internal communication of two elements or the interaction of two elements. For those of ordinary skill in the art, the specific meaning of the above terms of the present invention can be understood on a case-by-case basis.

In the present invention, unless otherwise expressly stated and defined, a first feature “above” or “under” a second feature may include that the first feature directly contacts with the second feature, and may also include that the first feature does not directly contact with the second feature. Moreover, the first feature “on”, “above” and “over” the second feature includes the first feature right above and oblique upper the second feature, or merely indicating that a level of the first feature is higher than a level of the second feature. The first feature “below”, “under” and “beneath” the second feature includes the first feature right below and oblique below the second feature, or merely indicating that a level of first feature is less than a level of the second feature.

The following disclosure provides many different embodiments or examples for implementing different structures of the present invention. In order to simplify the disclosure of the present invention, the components and arrangements of the specific examples are described below. Certainly, they are merely examples and are not intended to limit the invention. In addition, the present invention may be repeated with reference numerals and/or reference letters in the different examples, which are for the purpose of simplicity and clarity, and do not indicate the relationship between the various embodiments and/or arrangements discussed. Moreover, the present invention provides examples of various specific processes and materials, but one of ordinary skill in the art will recognize that other processes and/or the use of other materials can be used.

Please refer to FIG. 1. FIG. 1 is a schematic cross-sectional view and shows an encapsulation structure of an OLED device according to an embodiment of the present invention.

An embodiment according to the present invention provides an encapsulation structure of an organic light emitting diode (OLED) device, including:

a substrate 10 formed with the OLED device 101 and an encapsulation cover plate 20 disposed on the substrate 10, wherein the encapsulation cover plate 20 is provided with a first recess 201 and a second recess 202, the second recess 202 is surrounds the first recess 201, the OLED device 101 is disposed in the first recess 201, and an adhesive material is disposed in the second recess 202 to adhere and fix the encapsulation cover plate 20 to the substrate 10 formed with the OLED device 101.

Specifically, an anode (not shown) may be formed on the glass substrate 10 by radio frequency sputtering, and then an organic thin-film material and a metal cathode (not shown) are sequentially formed on the glass substrate 10 on which the anode is formed by an evaporation process. The encapsulation cover plate 20 is disposed on the glass substrate 10 formed with the OLEO device 101, and the encapsulation cover plate 20 is slit by laser to form the first recess 201 and the second recess 202. The second recess 202 is disposed surrounding the first recess 201, the OLED device 101 is disposed in the first recess 201, and the second recess 202 is filled with the adhesive material, so that the encapsulation cover plate 20 is adhered and fixed to the substrate 10 formed with the OLED device 101. It should be noted that a cross-sectional area of the first recess 201 is specifically determined according to the OLED device 101 to prevent the OLED device 101 from contacting with the encapsulation cover plate 20. Preferably, the first recess 201 may be a square shape, and the adhesive material filled in the second recess 202 may be an UV-curable adhesive. Specifically, when adhering encapsulation cover plate 20 to the substrate 10, the UV-curable adhesive in the second recess 202 can be irradiated by an ultraviolet light source, and the UV-curable adhesive is stimulated by the ultraviolet light source to glue and harden in a very short time.

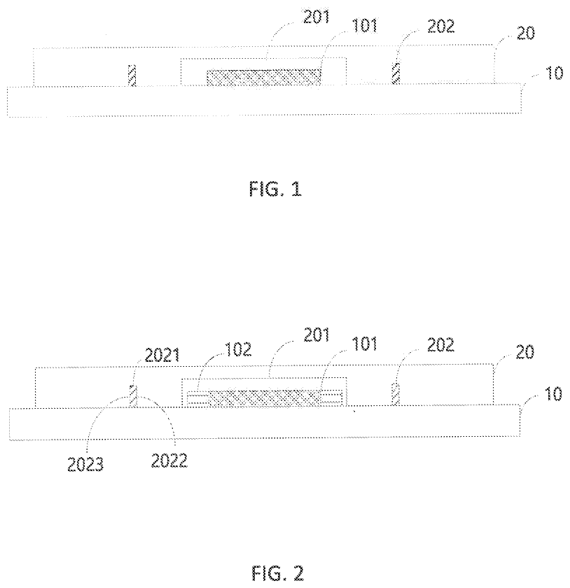

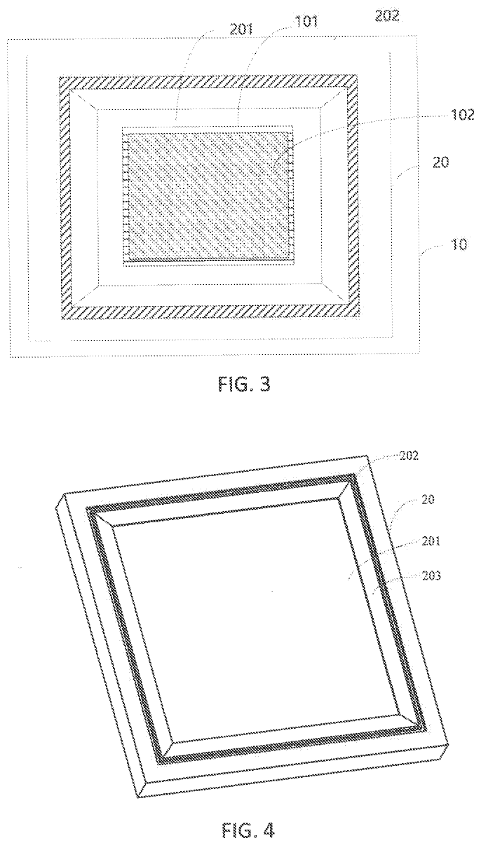

Then, please refer to FIG. 2 and FIG. 3, FIG. 2 is a schematic cross-sectional view and shows an encapsulation structure of an OLED device according to a preferred embodiment of the present invention, and FIG. 3 is a schematic plan view and shows an encapsulation structure of an OLED device according to a preferred embodiment of the present invention.

The encapsulation structure of the OLED device further includes a getter 102 disposed in the first recess 201, and the getter 101 surrounding the OLED device 101.

The second recess 202 includes an upper wall 2021; a first sidewall 2022 and a second sidewall 2023 disposed opposite to each other; the upper wall 2021 connected to the substrate 10, and the first sidewall 2022 disposed on a side of the upper wall 2021 adjacent to the first recess 201; wherein a distance between the first sidewall 2022 and the second sidewall 2023 ranges from 0.3 mm to 0.7 mm, and a distance between the first sidewall 2022 and the first recess 201 ranges from 1 mm to 5 mm.

A depth of the first recess 201 is greater than a depth of the second recess 202.

Specifically, a ring-shaped getter 102 is further disposed in the first recess 201, the ring-shaped getter 102 is disposed surrounding the OLED device 101, and a material of the getter 102 can be a desiccant for absorbing the external water and oxygen for an water-oxygen barrier. The second recess 202 includes the upper wall 2021, the first side wall 2022 and the second side wall 2023 disposed opposite to each other. The upper wall 2021 is connected to the substrate 10. The first sidewall 2022 disposed on the side of the upper wall 2021 adjacent to the first recess 201. Preferably, the distance between the first sidewall 2022 and the second sidewall 2023 is 0.5 mm; and the distance between the first sidewall 2022 and the first recess 201 is 3 mm, and the depth of the first recess 201 is greater than the depth of the second recess 202.

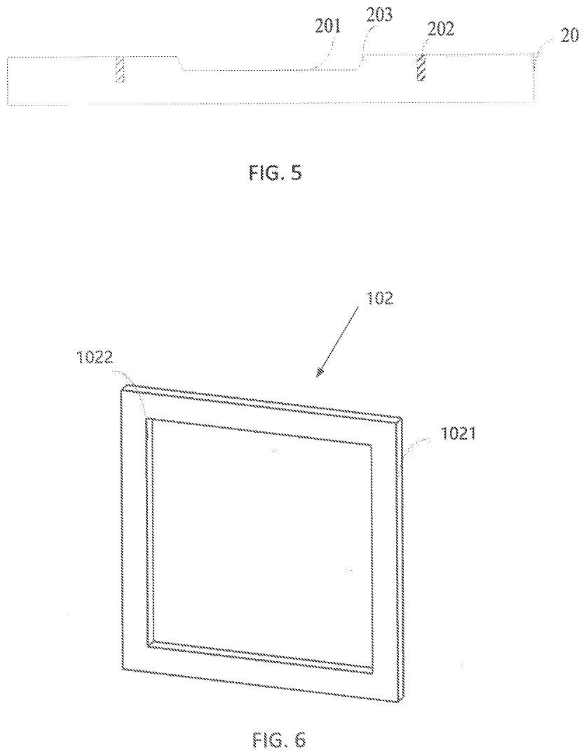

Furthermore, please refer to FIG. 4 and FIG. 5. FIG. 4 is a schematic structural representation of an encapsulation cover plate of an OLED device according to a preferred embodiment of the present invention. FIG. 6 is a schematic cross-sectional view of an encapsulation cover plate of an OLED device according to a preferred embodiment of the present invention.

Preferably, a chamfer 203 is further formed between the first recess 201 and the second recess 202, to avoid bubbles and discontinuous of connections from appearing when the encapsulation cover plate 20 is attached to the substrate 10.

Specifically, the chamfer 203 is formed on the encapsulation cover plate 20, the chamfer 203 is formed between the first recess 201 and the second recess 202, and the chamfer 203 surrounds the first recess 201. In the specific encapsulation, a UV curing method may be adopted, so that the encapsulation cover plate 20 is adhering to the substrate 10 through a sealant. During the adhering process, a part of the sealant is extruded by the encapsulation cover plate 20 and back to an inner side of the second recess 202, that is, the part of the sealant remains on the chamfer 203, so that avoids bubbles and discontinuous of connections from appearing.

The chamfer 203 is an acute angle, and an angle of the chamfer ranges from 5 to 15 degrees, Preferably, the angle of the chamfer is 10 degrees.

Since the inner side of the second recess 202 is subjected to a chamfer treatment with a small angle to form the chamfer 203, during the adhering process, the adhesive material between the substrate 10 and the encapsulation cover plate 20 is extruded and back to the inner side, so that avoids bubbles and discontinuous of connections from appearing during UV curing, thus achieving the purpose of improving the reliability of the OLED device encapsulation, and improving the capability of water and oxygen resistance of the OLED device, and prolonging the service life of the OLED device.

Please refer to FIG. 6, FIG. 6 is a schematic structural representation of a getter according to an embodiment of the present invention.

The getter 102 includes an outer sidewall 1021 and an inner sidewall 1022, and the outer sidewall 1021 and the inner sidewall 1022 are oppositely disposed:

The inner sidewall 1022 is disposed on a side of the getter 102 adjacent to the OLED device 101, and a distance between the inner sidewall 1022 and the outer sidewall 1021 ranges from 1 mm to 5 mm.

A material of the getter is selected from the group consisting of titanium, zirconium, tantalum or thorium.

Correspondingly, the present invention also provides an OLED display panel including an encapsulation structure of an OLED device according to any embodiment of the present invention.

In this embodiment, by providing a first recess 201 and a second recess 202 in the encapsulation cover plate, and disposing an adhesive material in the second recess 202, and providing a chamfer 203 between the first recess 201 and the second recess 202, to avoid bubbles and discontinuous connections from appearing during encapsulating, so that it improves the reliability of the OLED device encapsulation, water and oxygen resistance capabilities of the OLED device, and prolongs the service life of the OLED device.

The encapsulation structure and the display pan& of the OLEO device provided by the embodiments of the present invention are described in detail. The principles and implementations of the present invention are described in combination with specific embodiments. The above description of the embodiments is merely for the purpose of understanding the invention. In the meantime, for those skilled in the art, there will be changes in the specific implementation and application scope according to the idea of the present invention. In conclusion, the content of the specification of the present invention should not be construed as limitations of the scope of the present invention.

1. An encapsulation structure of an organic light-emitting diode (OLED) device, comprising:
a substrate formed with the OLED device and an encapsulation cover plate disposed on the substrate, wherein the encapsulation cover plate is provided with a first recess and a second recess, the second recess is surrounds the first recess, the OLED device is disposed in the first recess, and an adhesive material is disposed in the second recess to adhere and fix the encapsulation cover plate to the substrate formed with the OLED device; and
the encapsulation structure of the OLED device further comprising a getter disposed in the first recess, the getter surrounding the OLED device;
wherein a material of the getter is selected from the group consisting of titanium, zirconium, tantalum or thorium.

2. The encapsulation structure of the OLED device according to claim 1, wherein the second recess comprises an upper wall, a first sidewall and a second sidewall disposed opposite to each other; the upper wall connected to the substrate, and the first sidewall disposed on a side of the upper wall adjacent to the first recess;
wherein a distance between the first sidewall and the second sidewall ranges from 0.3 mm to 0.7 mm, and a distance between the first side all and the first recess ranges from 1 mm to 5 mm.

3. The encapsulation structure of the OLED device according to claim 2, wherein a depth of the first recess is greater than a depth of the second recess.

4. The encapsulation structure of the OLED device according to claim 2, wherein a chamfer is further formed between the first recess and the second recess, to avoid bubbles and discontinuous connections from appearing when the encapsulation cover plate is attached to the substrate.

5. The encapsulation structure of the OLED device according to claim 4, wherein the chamfer has an acute angle, and an angle of the chamfer ranges from 5 to 15 degrees.

6. The encapsulation structure of the OLED device according to claim 5, wherein the getter is a ring structure to increase a contact area of the getter with water and oxygen.

7. The encapsulation structure of an OLED device according to claim 6, wherein the getter comprises an outer sidewall and an inner sidewall, and the outer sidewall and the inner sidewall is disposed opposite to each other; and
wherein the inner sidewall is disposed on a side of the getter closed to the OLED device, and a distance between the inner sidewall and the outer sidewall ranges from 1 mm to 5 mm.

8. An encapsulation structure of an organic light-emitting diode (OLEO) device, comprising:
a substrate formed with the OLED device and an encapsulation cover plate disposed on the substrate,
wherein the encapsulation cover plate is provided with a first recess and a second recess, the second recess is surrounds the first recess, the OLED device is disposed in the first recess, and an adhesive material is disposed in the second recess to adhere and fix the encapsulation cover plate to the substrate formed with the OLED device.

9. The encapsulation structure of the OLED device according to claim 8, wherein the encapsulation structure of the OLED device further comprises a getter disposed in the first recess, and the getter surrounding the OLED device.

10. The encapsulation structure of the OLED device according to claim 8, wherein the second recess comprises an upper wall, a first sidewall and a second sidewall disposed opposite to each other; the upper wall connected to the substrate; and the first sidewall disposed on a side of the upper wall adjacent to the first recess,
wherein a distance between the first sidewall and the second sidewall ranges from 0.3 mm to 0.7 mm, and a distance between the first sidewall and the first recess ranges from 1 mm to 5 mm.

11. The encapsulation structure of the OLED device according to claim 10, wherein a depth of the first recess is greater than a depth of the second recess.

12. The encapsulation structure of the OLED device according to claim 10, wherein a chamfer is further formed between the first recess and the second recess, to avoid bubbles and discontinuous of connections from appearing when the encapsulation cover plate is attached to the substrate.

13. The encapsulation structure of the OLED device according to claim 12, wherein the chamfer has an acute angle, and an angle of the chamfer ranges from 5 to 15 degrees.

14. The encapsulation structure of the OLED device according to claim 13, wherein the getter is a ring structure to increase a contact area of the getter with water and oxygen.

15. The encapsulation structure of the OLED device according to claim 14, wherein the getter comprises an outer sidewall and an inner sidewall, and the outer sidewall and the inner sidewall is disposed opposite to each other; and
wherein the inner sidewall is disposed on a side of the getter closed to the OLED device, and a distance between the inner sidewall and the outer sidewall ranges from 1 mm to 5 mm.

16. The encapsulation structure of the OLED device according to claim 15, wherein a material of the getter is selected from the group consisting of titanium, zirconium, tantalum or thorium.

17. An organic light-emitting diode (OLEO) display panel comprising an encapsulation structure of an OLED device, the encapsulation structure of the OLED device comprising:
a substrate formed with the OLED device and an encapsulation cover plate disposed on the substrate,
wherein the encapsulation cover plate is provided with a first recess and a second recess, the second recess is surrounds the first recess, the OLED device is disposed in the first recess, and an adhesive material is disposed in the second recess to adhere and fix the encapsulation cover plate to the substrate formed with the OLED device.

18. The OLED display panel according to claim 17, wherein a depth of the first recess is greater than a depth of the second recess.

19. The OLEO display panel according to claim 17, wherein a chamfer is further formed between the first recess and the second recess, to avoid bubbles and discontinuous of connections from appearing when the encapsulation cover plate is attached to the substrate.

20. The OLEO display panel according to claim 19, wherein the chamfer has an acute angle, and an angle of the chamfer ranges from 5 to 15 degrees.
